(19) United States
(12) Patent Application Publication
(10) Pub. No.: US 2010/0319974 A1
(43) Pub. Date: Dec. 23, 2010

(54) PRINTED WIRING BOARD, ELECTRONIC DEVICE, AND METHOD FOR MANUFACTURING ELECTRONIC DEVICE

(76) Inventor: Naomi Ishizuka, Tokyo (JP)

Correspondence Address: Mr. Jackson Chen, 6535 N. STATE HWY 161, IRVING, TX, 75039, US

(21) Appl. No.: 12/865,203

(22) PCT Filed: Feb. 12, 2009
(86) PCT No.: PCT/JP2009/052298

§ 371 Date: Jul. 29, 2010

(30) Foreign Application Priority Data
Feb. 19, 2008 (JP) 2008-037605

(51) Int. Cl. H05K 1/16; H05K 1/11; B32B 37/02

(52) U.S. Cl. 174/260; 174/261; 156/60

(57) ABSTRACT

An electronic device comprises: a printed wiring board that comprises a substrate, pads formed on the substrate, and an insulating film layer covering a surface of the substrate on which the pads are formed; and an electronic element that comprises external terminals electrically connected to the pads and that is mounted on the printed wiring board. The insulating film layer comprises at least one connecting opening section each exposing at least part of one of the pads. At least part of an inner wall of the connecting opening section comprises at least one step section.

### REFERENCE TO RELATED APPLICATION

The present invention is the National Phase of PCT/JP2009/052298, filed Feb. 12, 2009, which is based upon and claims the benefit of the priority of Japanese patent application No. 2008-037605, filed on Feb. 19, 2008, the disclosure of which is incorporated herein in its entirety by reference thereto.

### TECHNICAL FIELD

The present invention relates to a printed wiring board. Further, it relates to an electronic device including an electronic element mounted on the printed wiring board and to a method for manufacturing the electronic device. In particular, it relates to an electronic device including an electronic element electrically connected to a printed wiring board by conductive paste and to a method for manufacturing the electronic device.

### BACKGROUND

Along with the recent rapid development of electronic devices, electronic elements having a higher function and a smaller size have been become available. Accordingly, even higher reliability is demanded for the electrical connection between these electronic elements and printed wiring boards. In recent years, in response to environmental issues, lead-free solder is demanded and various compositions have been considered. Lead-free solder can be largely divided into two types: one having a melting point higher than that of a conventional lead-containing solder and the other having a melting point lower than that of a conventional lead-containing solder. Examples of the lead-free solder having a higher melting point include Sn—Ag—Cu type solder (melting point: approximately 210° C. to 230° C.), Sn—Cu type solder (melting point: approximately 225° C. to 230° C.), and Sn—Zn type solder (approximately 190° C. to 200° C.). Examples of the lead-free solder having a lower melting point include Sn—Bi type solder (approximately 140° C.) and Sn—In type solder (approximately 130° C. to 190° C.). The lead-free solder having a lower melting point is somewhat inferior in reliability. For example, when heat is generated during an operation of a semiconductor and the ambient temperature is thereby increased close to the melting point, an opening may be caused by re-melting. Even if such opening is not caused, the bonding strength may be decreased rapidly, for example. Thus, since the lead-free solder having a lower melting point can only be used in a particular situation where the temperature is not increased more than the melting point, currently, the lead-free solder having a higher melting point, the Sn—Ag—Cu type solder in particular, is being mainly used.

Once connected, the lead-free solder having a higher melting point exhibits relatively high connection reliability. However, when mounted, if a thermal expansion difference between an electronic element and a printed wiring board is increased and a bend of a substrate or an electronic component is thereby increased, the lead-free solder may cause disconnection.

Thus, to reduce the thermal expansion difference, use of conductive paste that can be mounted at a lower temperature (approximately 130° C. to 200° C.) and that exhibits higher durability at a high temperature once hardened is being considered.

FIG. 16 is a schematic cross section of an electronic device using conductive paste according to background art. An electronic device 72 includes a printed wiring board 71 and an electronic element 73 mounted on the printed wiring board 71. Pads 75 for electrical connection and a solder resist film 76 are formed on a surface of the printed wiring board 71, and the solder resist film 76 has openings 77 in which the pads 75 are exposed. The openings 77 are filled with a conductive paste 78, and the pads 75 and external terminals (solder balls, for example) 80 of the electronic element 73 are electrically connected to each other by the conductive paste 78.

As for a semiconductor device disclosed in Patent Document 1, electrodes of a semiconductor package or a semiconductor chip are connected to electrodes of a mounting substrate by conductive resin balls, instead of solder balls.

### Patent Document 1:

### Japanese Patent Kokai Publication No: JP-P2000-332053 A

### SUMMARY

The entire disclosure of the above Patent Document 1 is incorporated herein by reference thereto. The following analysis is given by the present invention. As described above, when an electronic element is mounted in a low temperature environment, the electronic element and a printed wiring board are electrically connected by conductive paste.

However, generally, while conductivity of solder is approximately 10⁻⁶ mΩ·cm, conductivity of conductive paste for connecting an electronic element is approximately 10⁻⁵ mΩ·cm to 10⁻⁴ mΩ·cm. The conductivity of conductive paste can be increased by increasing the ratio of conductive particles in the conductive paste. However, if the ratio of the conductive particles included in the conductive paste is increased, the ratio of insulating resin components is accordingly decreased, resulting in a decrease of the bonding strength. On the other hand, the bonding strength between an electronic element and a printed wiring board can be increased by increasing the ratio of the insulating resin included in the conductive paste. However, if the ratio of the insulating resin components is increased, the ratio of the conductive particles is accordingly decreased, resulting in a decrease of conductivity. Namely, there is a trade-off relationship between the conductivity and the bonding strength of conductive paste. Thus, based on the connection manners in FIG. 16 and Patent Document 1, both the conductivity and the bonding strength cannot be increased.

In addition, currently, external terminals of most commercially available electronic elements are made of metal such as solder. It is actually difficult to replace these external terminals of commercially available electronic elements with conductive resin balls as disclosed in Patent Document 1. Thus, it is difficult to apply the technique disclosed in Patent Document 1 to an electronic element having metal terminals as external terminals.

It is an object of the present invention to provide a printed wiring board and an electronic device that can ensure both improved conductivity and bonding strength between an electronic element and the printed wiring board, even when conductive paste, particularly conductive paste having high conductivity, is used to electrically connect the electronic element and the printed wiring board. It is another object of the present invention to provide a method for manufacturing the electronic device.

According to a first aspect of the present invention, there is provided a printed wiring board comprising a substrate, pads formed on the substrate, and an insulating film layer covering a surface of the substrate on which the pads are formed. The insulating film layer comprises at least one connecting opening section each exposing at least part of one of the pads. At least part of an inner wall of the connecting opening section comprises at least one step section.

According to a preferable mode of the first aspect, the step section is formed so that adhesive material can be applied on the step section.

According to a preferable mode of the first aspect, the connecting opening section comprises: a first opening section formed for each of the pads so that at least part of each of the pads is exposed; and a second opening section that is formed on the first opening section and that is in communication with the first opening section. An opening area of the second opening section is larger than an opening area of the first opening section. The step section is formed in an area where the first and second opening sections do not overlap.

According to a preferable mode of the first aspect, the first and second opening sections are formed on a one-on-one basis.

According to a preferable mode of the first aspect, the first and second opening sections are formed concentrically.

According to a preferable mode of the first aspect, the connecting opening section comprises a plurality of first opening sections, and the second opening section overlaps with the plurality of first opening sections.

According to a preferable mode of the first aspect, the connecting opening section has a planar shape extending in one direction, and the step section is formed at least one end of the connecting opening section in a longitudinal direction of the connecting opening section.

According to a second aspect of the present invention, there is provided an electronic device comprising: a printed wiring board that comprises a substrate, pads formed on the substrate, and an insulating film layer covering a surface of the substrate on which the pads are formed; and an electronic element that comprises external terminals electrically connected to the pads and that is mounted on the printed wiring board. The insulating film layer comprises at least one connecting opening section each exposing at least part of one of the pads, and at least part of an inner wall of the connecting opening section comprises at least one step section. The external terminals are electrically connected to the pads by conductive paste applied on the pads, and the electronic element is bonded to the printed wiring board by adhesive material applied on the step section.

According to a preferable mode of the second aspect, the connecting opening section comprises: a first opening section formed for each of the pads so that at least part of each of the pads is exposed; and a second opening section that is formed on the first opening section and that is in communication with the first opening section. An opening area of the second opening section is larger than an opening area of the first opening section, and the first and second opening sections are formed on a one-on-one basis. The step section is formed in an area where the first and second opening sections do not overlap, and the external terminals of the electronic element are bonded to the insulating film layer by the adhesive material.

According to a preferable mode of the second aspect, the connecting opening section comprises: a plurality of first opening sections each formed for one of the pads so that at least part of each of the pads is exposed; and a second opening section that is formed on the first opening sections and that is in communication with the first opening sections. An opening area of the second opening section is larger than an opening area of each of the first opening sections, and the second opening section overlaps with the plurality of first opening sections. The step section is formed in an area where the first and second opening sections do not overlap, and at least part of a side surface of the electronic element is bonded to the insulating film layer by the adhesive material.

According to a preferable mode of the second aspect, the connecting opening section comprises: a first opening section formed for each of the pads so that at least part of each of the pads is exposed; and a second opening section that is formed on the first opening section and that is in communication with the first opening section. An opening area of the second opening section is larger than an opening area of the first opening section. The connecting opening section has a planar shape extending in one direction. The step section is formed at least one end of the connecting opening section in a longitudinal direction of the connecting opening section in an area where the first and second opening sections do not overlap. Each of the external terminals has a strip shape, is arranged in a longitudinal direction of the connecting opening section, and is bonded to the insulating film layer by the adhesive material.

According to a preferable mode of the second aspect, the connecting opening section is filled with at least the conductive paste and the adhesive material, and the adhesive material is applied extending from the step section to a surface of the insulating film layer.

According to a third aspect of the present invention, there is provided a method for manufacturing an electronic device in which an electronic element is mounted on a printed wiring board. The method comprises: forming a printed wiring board comprising an insulating film layer covering a surface of a substrate on which a pad is formed and at least one connecting opening section exposing at least part of the pad, at least part of an inner wall of the connecting opening section comprising at least one step section; applying conductive paste on the pad for electrically connecting an external terminal of the electronic element and the pad; applying adhesive material on the step section; mounting the electronic element on the printed wiring board so that the external terminal is positioned in the connecting opening section; and hardening the conductive paste and the adhesive material to electrically connect the external terminal and the pad by the conductive paste and to bond the printed wiring board and the electronic element by the adhesive material.

According to a preferable mode of the third aspect, the external terminal and the insulating film layer are bonded by the adhesive material.

According to a preferable mode of the third aspect, at least part of a side surface of the electronic element and the insulating film layer are bonded by the adhesive material.

According to the present invention, at least one of the following meritorious effects can be obtained.

According to the present invention, since the adhesive material can be applied on the step section(s) of the connecting opening section(s), in addition to the bonding strength provided by the conductive paste, the printed wiring board and an electronic element can be bonded by the bonding strength provided by the adhesive material. Thus, even when such conductive paste that has a high conductivity and a low bonding strength is used, a sufficient bonding strength between the printed wiring board and an electronic element can be ensured. Therefore, the electrical connection reliability can be increased. Namely, according to the present invention, both the conductivity and the bonding strength can be increased.

According to the present invention, since the adhesive material having a high flexibility holds an electronic element, a thermal expansion difference between the printed wiring board and the electronic element in a planar (horizontal) direction can be absorbed. Thus, an obtained electronic device has less stress at connection parts thereof. In addition, since the conductive paste is used, an electronic element can be mounted in a low temperature environment. Thus, an electronic device having a higher connection reliability can be obtained.

According to the present invention, the step section(s) formed by the connecting opening section(s) can function as a positioning mask(s) when an external terminal(s) (solder balls, for example) of an electronic element is arranged. Thus, displacement of the electronic element or a short-circuit between neighboring pads can be prevented. Additionally, productivity of electronic devices can be increased.

According to the present invention, the connecting opening section(s) can be easily changed to have a suitable mode (shape, size, and the like) for an electronic element or an external terminal(s) of the electronic element, depending on a mode (shape, size, and the like) of the electronic element or the external terminal(s) thereof. In addition, depending on a mode of the connecting opening section(s) and properties (conductivity, connection reliability, and the like) of an electronic element, the amount of the conductive paste and the adhesive material can be adjusted suitably. Thus, various types of electronic elements of different properties can be mounted on a single printed wiring board. In addition, manufacturing costs can be reduced.

### BRIEF DESCRIPTION OF THE DRAWINGS

FIG. 1 is a schematic cross section of the printed wiring hoard according to the first exemplary embodiment of the present invention.

FIG. 2 is a schematic partial plan view of a connecting opening section of the printed wiring board illustrated in FIG. 1.

FIG. 3 is a schematic partial cross section of the connecting opening section of the printed wiring board taken along line in FIG. 2.

FIG. 4 is a schematic partial cross section of another mode of the connecting opening section, different from those of FIGS. 1 to 3, of the printed wiring board according to the first exemplary embodiment.

FIG. 5 is a schematic partial cross section of another mode of the connecting opening section, different from those of FIGS. 1 and 3, of the printed wiring board according to the first exemplary embodiment.

FIG. 6 is a schematic partial cross section of another mode of the connecting opening section, different from those of FIGS. 1 and 3, of the printed wiring board according to the first exemplary embodiment.

FIG. 7 is a schematic partial plan view of another mode of the connecting opening section, different from that of FIG. 2, of the printed wiring board according to the first exemplary embodiment.

FIG. 8 is a schematic cross section of an electronic device according to the first exemplary embodiment of the present invention.

FIGS. 9A to 9E are schematic partial cross sections illustrating processes for mounting an electronic element on the printed wiring board.

FIG. 10 is a schematic plan view of a printed wiring board according to a second exemplary embodiment of the present invention.

FIG. 11 is a schematic cross section of the printed wiring board taken along line XI-XI in FIG. 10.

FIGS. 12A to 12E are schematic partial cross sections illustrating processes for mounting an electronic element on the printed wiring board.

FIG. 13 is a schematic partial plan view of a connecting opening section of a printed wiring board according to a third exemplary embodiment of the present invention.

FIG. 14 is a schematic cross section of the printed wiring board taken along line XIV-XIV in FIG. 13.

FIG. 15 is a schematic partial cross section of an electronic device according to the third exemplary embodiment of the present invention.

FIG. 16 is a schematic cross section of an electronic device according to background art.

### EXPLANATIONS OF SYMBOLS

Refer to the end of the Description for explanation of symbols.

### PREFERRED MODES

A printed wiring board, an electronic device, and a method for manufacturing the printed wiring board and the electronic device according to a first exemplary embodiment of the present invention will be hereinafter described.

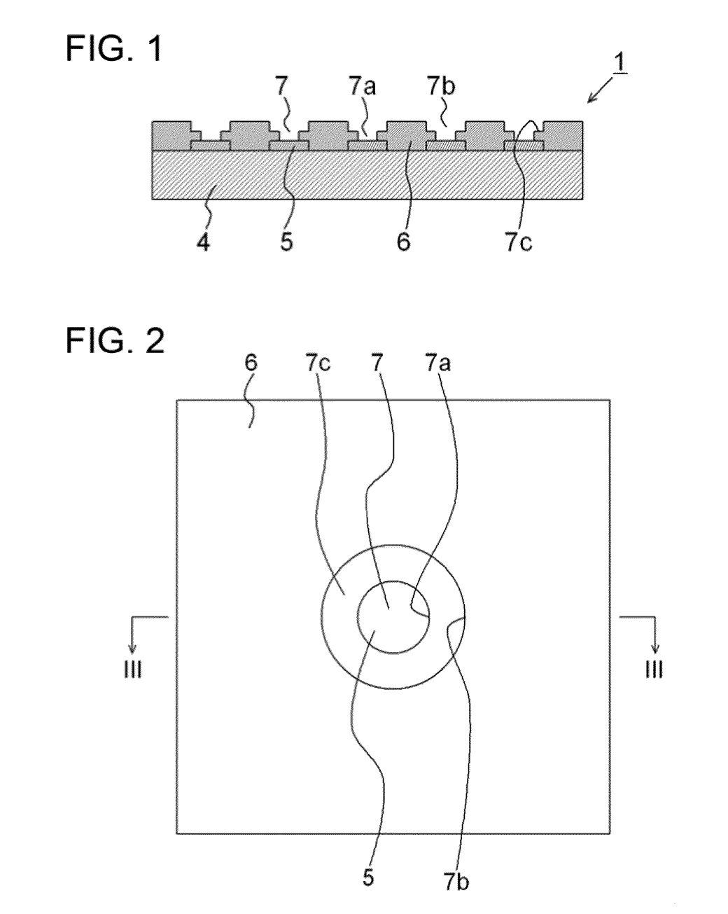

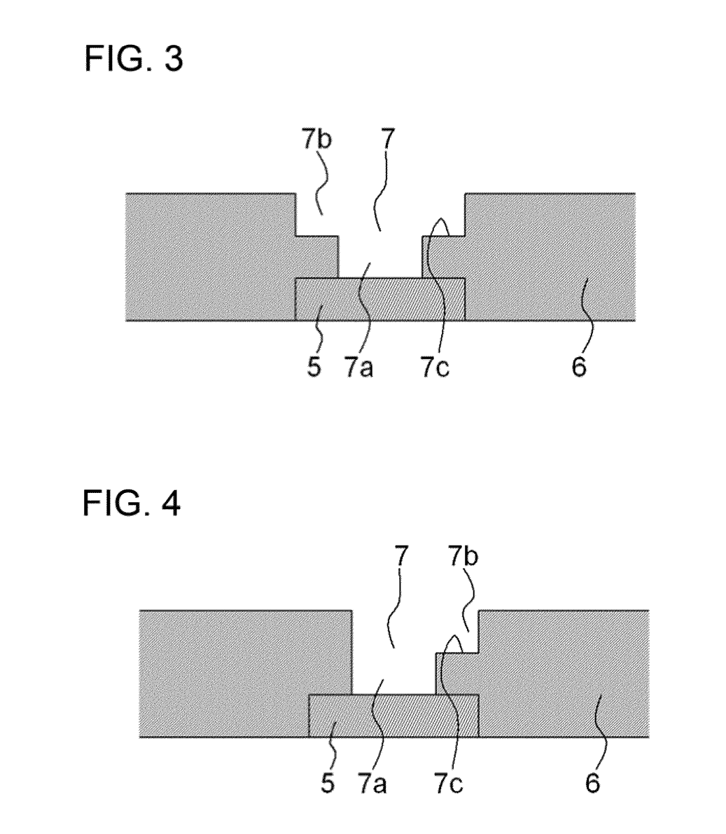

First, the printed wiring board according to the first exemplary embodiment of the present invention will be described. FIG. 1 is a schematic cross section of the printed wiring board according to the first exemplary embodiment of the present invention. FIG. 2 is a schematic partial plan view of a connecting opening section of the printed wiring board illustrated in FIG. 1. FIG. 3 is a schematic partial cross section of the connecting opening section of the printed wiring board, taken along line in FIG. 2. A printed wiring board 1 includes: a substrate 4 including at least one wiring layer (not illustrated) and at least one insulating layer (not illustrated); pads 5 formed on a surface of the substrate 4 and used for electrical connection to an electronic element; and an insulating film layer 6 formed to cover a surface of the substrate 4 on which the pads 5 are formed. Connecting opening sections 7 are formed in the insulating film layer 6, so that at least part of each of the pads 5 is exposed.

At least part of an inner wall of each of the connecting opening sections 7 comprises at least one step section 7c. Each connecting opening section 7 is divided by the step section 7c into a first opening section (conductive opening section) 7a and a second opening section (adhesive opening section) 7b. Namely, each of the connecting opening sections 7 includes a first opening section 7a formed on a pad 5 and a second opening section 7b formed on the first opening section 7a. Each connecting opening section 7 includes sections where the first opening section 7a and the second opening section 7b do not overlap, and at least one of these sections forms at least one step section 7c. It is preferable that the first and second opening sections 7a and 7b be in communication with each other so that the opening area of each connecting opening section 7 decreases from the outside direction toward the pad 5 direction. Each step section 7c is formed so that adhesive material can be applied thereon, and preferably, each step section 7c extends in a direction parallel to the surface of the substrate 4. It is preferable that an opening area of each second opening section 7b be larger than that of each first opening section 7a. In the present exemplary embodiment, it is preferable that each pair of first and second opening sections 7a and 7b is formed concentrically.

In FIGS. 1 to 3, each step section 7c is formed along the entire circumference of a corresponding connecting opening section 7. However, as illustrated in FIG. 4, each step section 7c may be formed only at a part of a corresponding connecting opening section 7. The connecting opening section 7 may be present in plurality, and each connecting opening section 7 may include a plurality of step sections 7c.

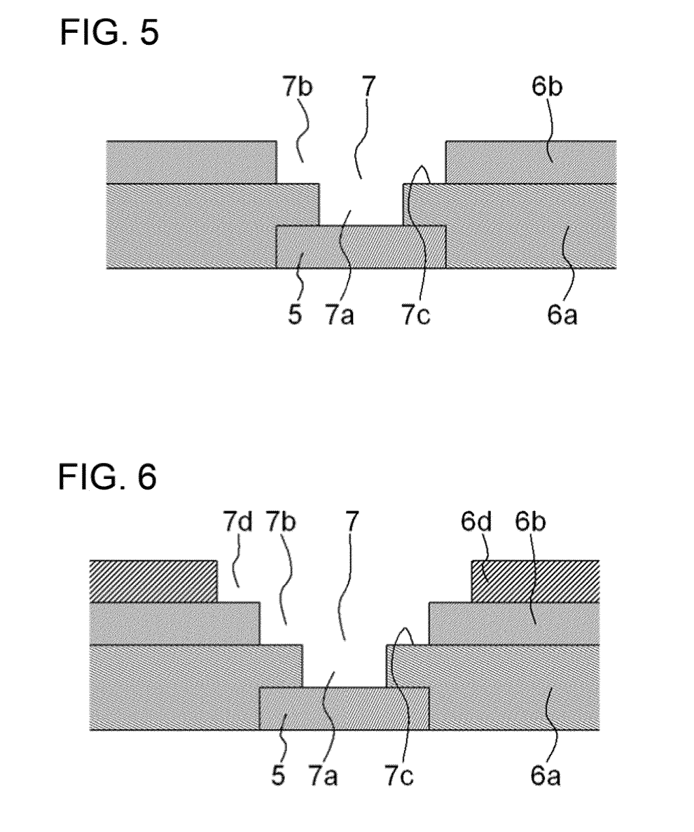

In the mode illustrated in FIGS. 1 and 3, a single insulating film layer 6 is used to form the connecting opening sections 7 having at least one step section. However, the present invention is not limited to such mode. Various modes may be adopted for the connecting opening sections. For example, as illustrated in FIG. 5, a plurality of insulating film layers 6 may be formed. In a mode illustrated in FIG. 5, a first insulating film layer 6a is used to form the first opening sections 7a, and a second insulating film layer 6b is used to form the second opening sections 7b. Alternatively, as illustrated in FIG. 6, three or more insulating film layers 6a, 6b, and 6d may be used to form third opening sections (second adhesive opening sections) 7d. In this way, connecting opening sections 7 each having two or more steps can be formed.

The insulating film layer 6 may be made of an arbitrary material, as long as the material has an insulating property and can maintain shapes of the connecting opening sections. Thus, material of the insulating film layer 6 is not particularly limited. For example, a solder resist film may be used as the insulating film layer 6. Further, if a plurality of insulating film layers 6 are formed as illustrated in FIGS. 5 and 6, the plurality of insulating layers may be made of an identical material or different materials.

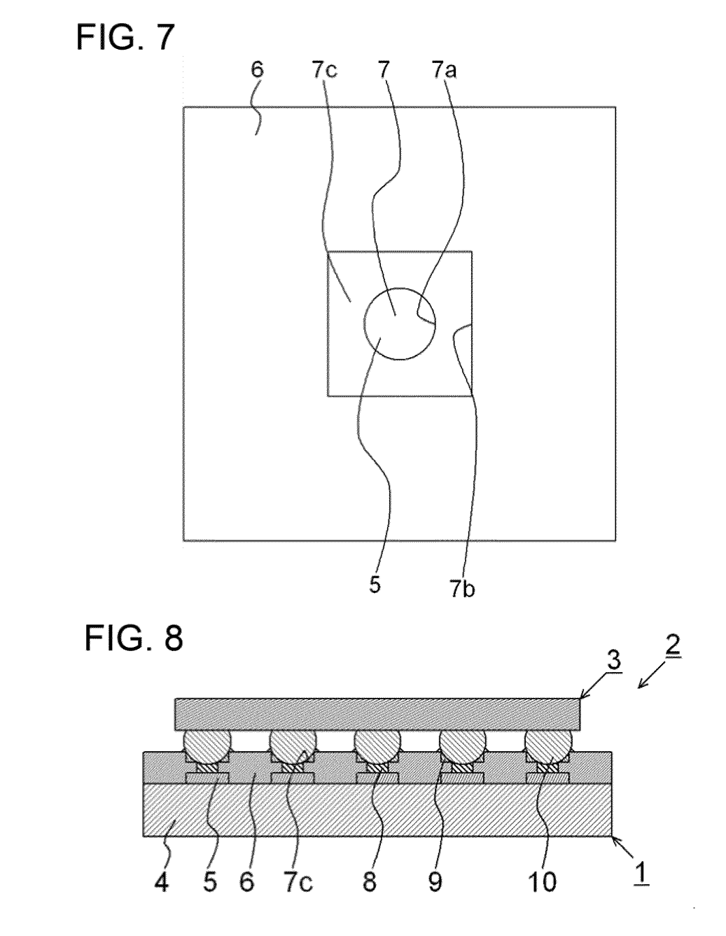

While the planar shape of the connecting opening section 7 is circular in FIG. 2, the planar shape of each connecting opening section 7 is not limited to circular. Various modes may be applicable for the connecting opening sections 7; for example, the planar shape of each of the connecting opening section 7 may be polygonal or elliptical. The first and second opening sections 7a and 7b may have an identical planar shape or different planar shapes as illustrated in FIG. 7.

Next, an electronic device according to the first exemplary embodiment of the present invention will be described. FIG. 8 is a schematic cross section of the electronic device according to the first exemplary embodiment. An electronic device 2 is formed by mounting an electronic element 3 on the printed wiring board 1 according to the first exemplary embodiment of the present invention illustrated in FIGS. 1 to 3.

External terminals 10 of the electronic element 3 are arranged in the first and second opening sections 7a and 7b that are in communication with each other. The external terminals 10 and the pads 5 are bonded and electrically connected by a conductive paste 8. The conductive paste 8 is mainly applied in each of the first opening sections 7a between an external terminal 10 and a pad 5.

Material of the conductive paste 8 is not particularly limited, as long as constituent components of the conductive paste 8 ensure sufficient electrical conductivity. The type, size, and content of conductive particles as well as use of resin are not particularly limited. For example, a mixture of conductive particles and resin components (termed as “conductive resin”) can be used as the conductive paste 8. Such conductive resin ensures electrical continuity, as the resin components contract and the conductive particles come into contact with each other. It is preferable that the resin components in the conductive resin be mixed within a range that does not inhibit the conductive property (20 wt % or less, for example). For example, metal particles such as Ag, Cu, or Ni can be used as the conductive particles. Alternatively, particles on which a conductive surface treatment has been applied can be used, examples of which include resin particles or ceramic particles. As the resin components, for example, an insulating resin such as epoxy resin, silicon resin, a phenol resin, diallyl phthalate resin, polyimide resin, acrylic resin, or urethane resin can be used.

Alternatively, nano paste made of material including nanosized conductive particles and dispersant as primary components can be used as the conductive paste. Further, conductive paste made of self-melting conductive particles such as lead-free solder with a low melting point may be used (cream solder, for example). By using nanosized conductive particles or self-melting conductive particles, higher conductivity can be ensured. Further, based on the structure according to the present invention, even if re-melted in a reheating process carried out later, since connection is maintained by the upper adhesive material, no opening or peeling is caused.

The external terminals 10 of the electronic element 3 and the insulating film layer 6 are bonded to each other by an adhesive material 9 as well. The adhesive material 9 is mainly applied on the insulating film layer 6 (step sections 7c) in the second opening sections 7b. In addition to the step sections 7c, the adhesive material 9 may be applied to a surface of the insulating film layer 6 outside the connecting opening section 7, to bond the insulating film layer 6 and the external terminals 10.

The type of the adhesive material 9 is not limited as long as sufficient adhesion strength can be ensured. For example, material having epoxy resin, silicon resin, phenol resin, diallyl phthalate resin, polyimide resin, acrylic resin, urethane resin, or the like as a primary component can be used. As long as the adhesion strength is not adversely affected, the adhesive material 9 may include conductive particles.

Unless completely mixed in the connecting opening sections 7, part of the conductive paste 8 and part of the adhesive material 9 may be mixed in the connecting opening sections 7. Namely, an overspill of the conductive paste 8 from the first opening sections 7a or an overspill of the adhesive material 9 from the second opening sections 7b is not problematic.

Next, a method for manufacturing the printed wiring board and the electronic device according to the first exemplary embodiment of the present invention will be described.

First, a method for manufacturing the printed wiring board 1 will be described. A paper substrate, a glass substrate, a polyester fiber substrate, or the like is impregnated with epoxy resin, phenol resin, or the like, to form an insulating layer. Next, as a wiring layer, copper foil is attached through pressure and heat treatments, so as to form a copper-clad laminated board. A photosensitive resin is applied to a surface of the copper-clad laminated hoard. Next, by using a mask for forming a wiring pattern, the wiring pattern section alone is exposed and developed. In this way, an etching resist having a shape identical to the wiring, pattern is formed. Subsequently, the surface of the copper-clad laminated board is etched, and copper formed at portions other than the portion where the etching resist is formed is removed. Next, by removing the etching resist, a copper wiring pattern is formed. In this way, the substrate 4 is manufactured (the above processes are not illustrated). The above processes illustrate a method for manufacturing the substrate 4 of a single-sided single-layer type, and therefore, to manufacture a multilayer substrate, wirings are formed on both sides of the substrate, and copper-clad laminated boards are laminated on the topmost surfaces. Additionally, vias for obtaining electrical conduction through the individual layers are formed, and pattern formation is carried out again based on the method as described above.

Next, to protect the wiring layer, an insulating film layer 6 (solder resistor, for example) having the connecting opening sections 7 is formed on the pads 5. Namely, a surface of the substrate 4 is covered with the insulating film layer 6. In this way, the printed wiring board 1 is manufactured (the process is not illustrated).

A method for manufacturing the first and second opening sections 7a and 7b is not particularly limited. Various methods can be suitably adopted. For example, a dry film including the first and second opening sections 7a and 7b may be used as the insulating film layer 6, and the dry film may be adhered to the substrate 4. Alternatively, the insulating film layer 6 having the connecting opening sections 7 may be formed, by forming a first insulating film layer having only the first opening sections 7a by using liquid resist or the like and forming a second insulating film layer having the second opening sections 7b on the first insulating film layer after the liquid resist film hardens.

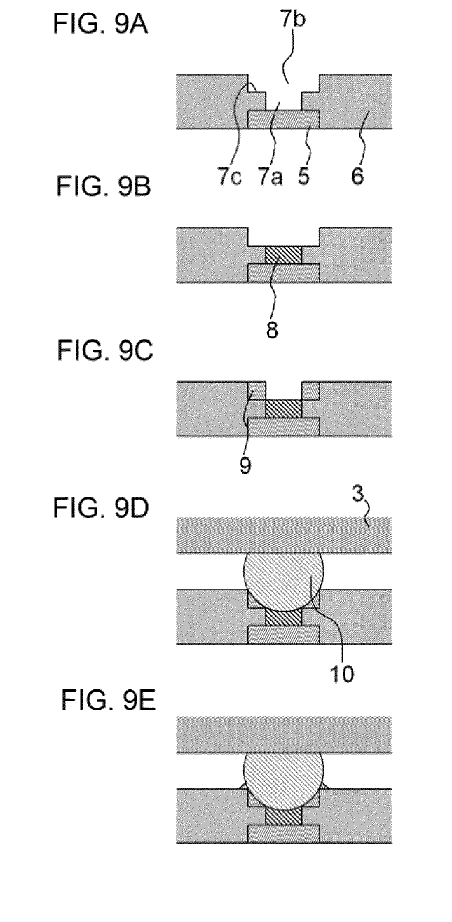

Next, the electronic element 3 (ball grid array (BGA) semiconductor element, for example) is mounted on the printed wiring board 1. FIGS. 9A to 9E are schematic partial cross sections illustrating processes for mounting the electronic element on the printed wiring board. First, the conductive paste 8 for electrically connecting the external terminals 10 of the electronic element 3 and the pads 5 is applied in the first opening sections 7a (FIG. 9A) on the pads 5 of the printed wiring board 1 (FIG. 9B). To apply the conductive paste 8, a suitable method can be selected among various methods, such as a printing method using a screen plate, a dispensing method, or an inkjet method. Next, the adhesive material 9 for increasing the adhesion strength between the external terminals 10 of the electronic element 3 and the insulating film layer 6 is applied on the step sections 7c in the second opening sections 7b (FIG. 9C). As in the method for applying the conductive paste 8, to apply the adhesive material 9, a suitable method can be selected among various methods.

Next, the electronic element 3 is mounted on the printed wiring board, so that part of each of the external terminals 10 of the electronic element 3 is connected to the conductive paste 8 and another part of each of the external terminals 10 is connected to the adhesive material 9 (FIG. 9D). In this step, the step sections 7c of the connecting opening sections also function as masks during positioning. Next, the printed wiring board on which the electronic element 3 is mounted is heated to harden the conductive paste 8 and the adhesive material 9. As a result, the external terminals 10 are firmly adhered to the printed wiring board (FIG. 9E). The printed wiring board can be heated by a heat source such as an oven, a reflow furnace, or a hot plate. It is preferable that the heating be carried out at a temperature (150° C. to 180° C., for example) lower than 230° C. which is a minimum heating temperature of Sn—Ag—Cu solder. If the hardening conditions of the conductive paste 8 and the adhesive material 9 are identical or similar, the conductive paste 8 and the adhesive material 9 can be hardened at one time. If the hardening conditions are different, the conductive paste 8 and the adhesive material 9 can be hardened in stages.

In the above description, a printed wiring board having an electronic element on one side of the printed wiring hoard, an electronic device, and a method for manufacturing the printed wiring board and the electronic device have been described. However, needless to say, electronic elements can be mounted on both sides of the printed wiring board based on the same method. The shape of each of the elements is not limited to the shapes illustrated in the drawings. For example, the shape of each of the external terminals is not limited to spherical as illustrated in FIGS. 9D and 9E. The shape of each of the external terminals may be convex or the like.

According to the present exemplary embodiment, the step sections are formed in the connecting opening sections, and in addition to the conductive paste, the adhesive material can be applied. Thus, a high conductivity can be ensured by the conductive paste, and the adhesion strength between the electronic element and the printed wiring board can be increased by the adhesive material. Further, since the adhesive material having a high flexibility holds the electronic element, the adhesive material can absorb a planar-direction thermal expansion difference between the printed wiring board and the electronic element. Furthermore, since the conductive paste is used in a manufacturing process of the electronic device, the heating temperature can be decreased. In addition, the connecting opening sections having the step sections also function as positioning masks. Thus, by using the printed wiring board of the present invention, an electronic device having a high electrical connection reliability, a lower risk for damage, and a higher productivity can be provided. In addition, a method for manufacturing the electronic device can be provided.

Next, a printed wiring board, an electronic device, and a method for manufacturing the printed wiring board and the electronic device according to a second exemplary embodiment of the present invention will be hereinafter described.

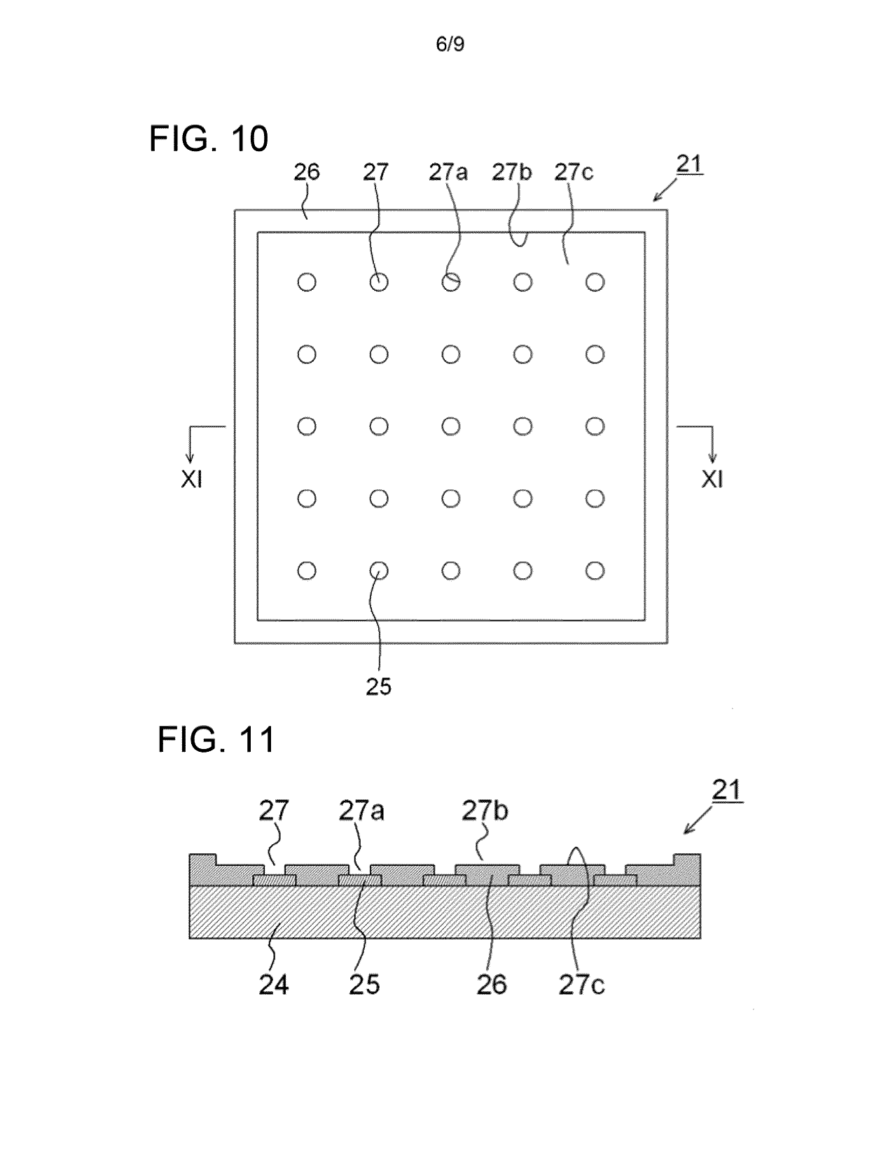

First, a printed wiring board according to the second exemplary embodiment of the present invention will be described. FIG. 10 is a schematic plan view of a printed wiring board according to a second exemplary embodiment of the present invention, and FIG. 11 is a schematic cross section of the printed wiring board, taken along line XI-XI in FIG. 10. The connecting opening section according to the second exemplary embodiment has a different mode from that according to the first exemplary embodiment. While a single first opening section is formed for a single second opening section according to the first exemplary embodiment, a single second opening section 27b is formed for a plurality of first opening sections 27a according to the second exemplary embodiment. It is preferable that the second opening section 27b have a circumference (opening area) larger than a circumference (mount area) of a mounted electronic component.

Based on a printed wiring board 21, an insulating film layer 26 includes a connecting opening section 27 in which at least part of each of the pads 25 is exposed. At least part of an inner wall of the connecting opening section 27 forms a step section 27c. The connecting opening section 27 includes: a plurality of first opening sections 27a in which at least part of each of the pads 25 is exposed; a step section 27c; and at least one second opening section 27b that encompasses the plurality of first opening sections 27a (overlaps with the plurality of first opening sections 27a) and that is formed on the first opening sections 27a. The first and second opening sections 27a and 27b are in communication with each other. The step section 27c is formed so that adhesive material can be applied thereon, and it is preferable that the step section 27c extend in a direction parallel to a surface of a substrate 24. The second opening section 27b has an opening area larger than that of each of the first opening sections 27a.

When an electronic element is mounted on the printed wiring board 21, a conductive paste is mainly applied in the first opening sections 27a, and adhesive material is mainly applied on the step section 27c in the second opening section 27b.

Other than the mode of the second opening section, modes of the printed wiring board 21 according to the second exemplary embodiment are the same as those of the printed wiring board according to the first exemplary embodiment.

Except to the second opening section, the printed wiring board 21 according to the second exemplary embodiment can be manufactured by a method similar to the printed wiring board manufacturing method described in the first exemplary embodiment.

Next, an electronic device according to the second exemplary embodiment of the present invention and a method for manufacturing the electronic device will be described.

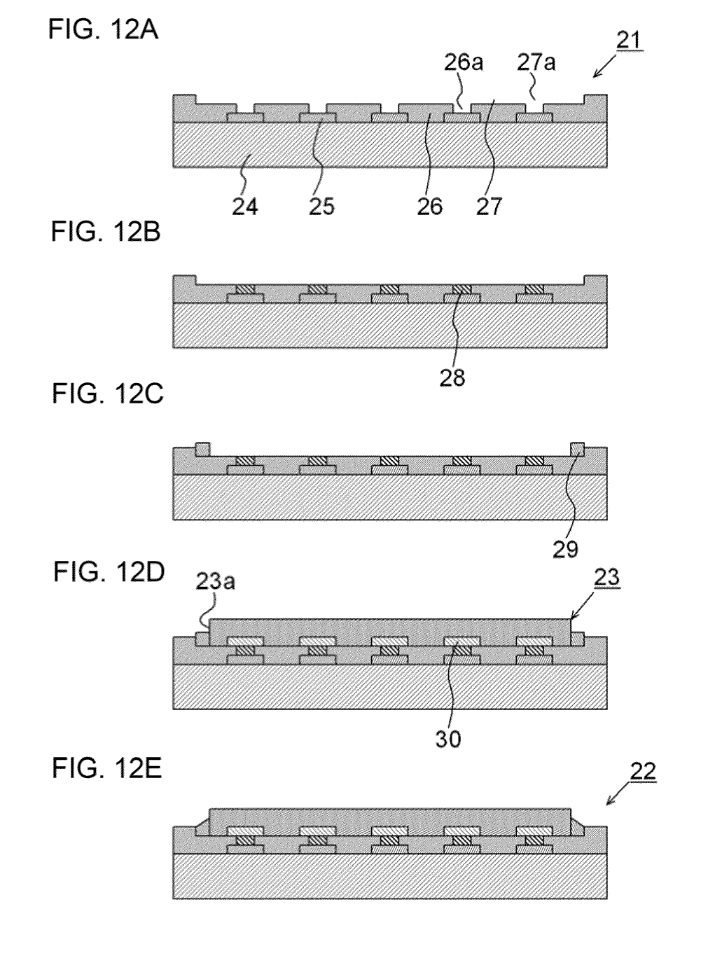

FIGS. 12A to 12E are schematic cross sections of the electronic device according to the second exemplary embodiment and illustrate a method for manufacturing the electronic device.

First, an electronic device according to the second exemplary embodiment in which an electronic element 23 (land grid array (LGA) semiconductor element, for example) is mounted on the printed wiring board 21 will be described. According to the first exemplary embodiment, the adhesive material is in contact with the external terminals. However, based on an electronic device 22 illustrated in FIG. 12E, an adhesive material 29 is not in contact with external terminals 30 of the electronic element 23. The adhesive material 29 is in contact with at least part of at least one side surface 23a of the electronic element 23. Namely, the side surface 23a of the electronic element 23 and the insulating film layer 26 are bonded by the adhesive material 29. Further, the electronic element 23 is disposed on the step section 27c of the opening section 27. Namely, the electronic element 23 is fitted in the second opening section 27b. The external terminals 30 of the electronic element 23 and the pads 25 are electrically connected to each other by a conductive paste 28 applied in the first opening sections 27a.

Next, a method for manufacturing the electronic device according to the second exemplary embodiment will be described. First, the conductive paste 28 is applied in the first opening sections 27a on the pads 25 of the printed wiring board 21 (FIG. 12A) according to the second exemplary embodiment (FIG. 12B). The conductive paste 28 is applied so that the external terminals 30 and the pads 25 can be electrically connected to each other when the planar external terminals 30 of the electronic element 23 are arranged. Next, the adhesive material 29 is applied along at least part of the circumference of the second opening section 27b on the step section 27c of the second opening section 27b (FIG. 12C).

Next, the electronic element 23 is mounted on the printed wiring board 21, so that at least part of each of the external terminals 30 of the electronic element 23 is in contact with the conductive paste 28 and at least part of at least one side surface of the electronic element 23 is in contact with the adhesive material 29 (FIG. 12D). Next, a heat treatment is carried out to harden the conductive paste 28 and the adhesive material 29. In this way, the electronic device 22 can be manufactured.

Other than the above mode, the electronic device manufacturing method according to the present exemplary embodiment is the same as that according to the first exemplary embodiment.

The present exemplary embodiment is suitable for mounting an electronic element that does not have protruding external terminals but planar external terminals, such as an LGA semiconductor element, a chip capacitor, and a chip resistor. The present exemplary embodiment can provide meritorious effects similar to those provided by the first exemplary embodiment.

Next, a printed wiring board; an electronic device, and a method for manufacturing the printed wiring board and the electronic device according to a third exemplary embodiment of the present invention will be hereinafter described.

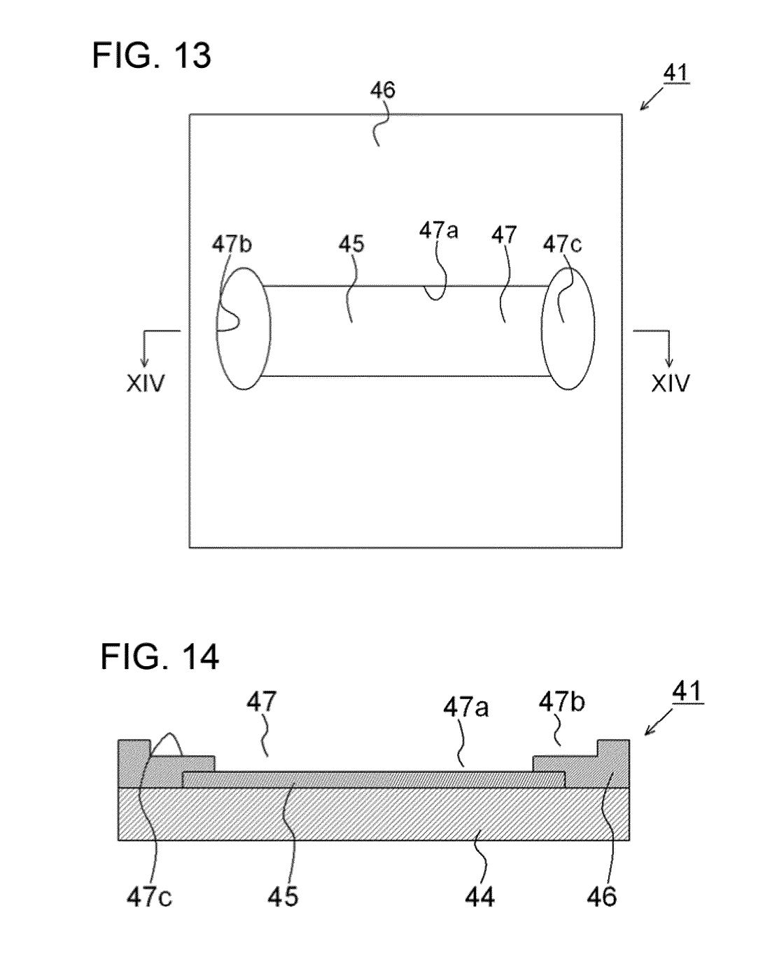

First, a printed wiring board according to the third exemplary embodiment of the present invention will be described. FIG. 13 is a schematic partial plan view of a connecting opening section of a printed wiring board according to the third exemplary embodiment of the present invention, and FIG. 14 is a schematic cross section of the printed wiring board, taken along line XIV-XIV in FIG. 13. A printed wiring board 41 according to the present exemplary embodiment is suitable when an electronic element having a strip-shaped external terminal (a lead, for example) that protrudes in a side surface direction is mounted. Examples of such electronic element include a quad flat package (QFP) and a thin small outline package (TSOP).

Based on the printed wiring board 41, an insulating film layer 46 includes a connecting opening section 47 in which at least part of a pad 45 is exposed. At least part of an inner wall of the connecting opening section 47 forms a step section 47c. The connecting opening section 47 includes: a first opening section 47a having a long planar shape in one direction (a rectangular shape, for example) in which at least part of the pad 45 is exposed; and a second opening section 47b formed on the first opening section 47a so that a step section 47c is formed at least one end of the second opening section 47b in a longitudinal direction of the first opening section 47a. The first and second opening sections 47a and 47b are in communication with each other. The step section 47c is formed so that adhesive material can be applied thereon, and it is preferable that the step section 47c extend in a direction parallel to a surface of the substrate 44. The second opening section 47b has an opening area larger than that of the first opening section 47a. In a mode illustrated in FIG. 13, two step sections 47c are formed at both ends of the connecting opening section 47 in a longitudinal direction thereof. However, the position and the number of the step sections 47c can be suitably changed depending on a mode of a mounted electronic element or required reliability. Further, while FIG. 13 illustrates the step sections 47c each having an elliptical planar shape, the step sections 47c are not limited to such shape. It is preferable that opening areas of the first and second opening sections 47a and 47b be suitably determined depending on an area of contact with an external terminal of an electronic element.

When an electronic element is mounted on the printed wiring board 41, conductive paste is mainly applied in the first opening section 47a, and adhesive material is mainly applied on the step sections 47c in the second opening section 47b.

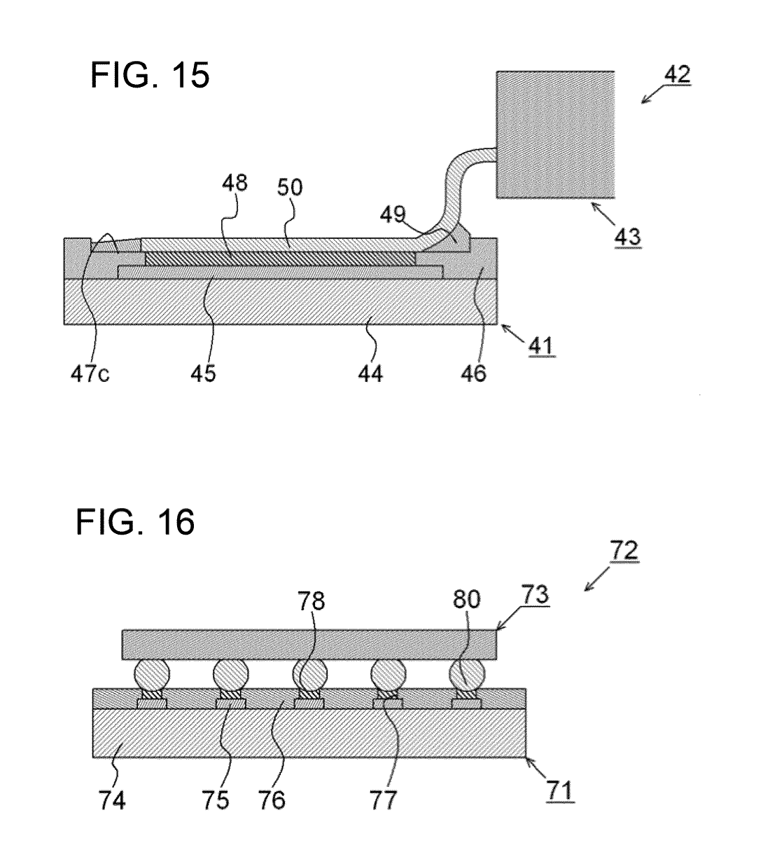

Next, an electronic device according to the third exemplary embodiment in which an electronic element is mounted on the printed wiring board 41 will be described. FIG. 15 is a schematic partial cross section of an electronic device according to the third exemplary embodiment of the present invention. Part of a strip-shaped external terminal 50 protruding from an electronic element 43 in a side surface direction thereof is arranged in the second opening section 47b. The part of the external terminal 50 is electrically connected to the pad 45 of the printed wiring board 41 by a conductive paste 48 applied in the first opening section 47a.

An adhesive material 49 is applied on the step sections 47c, at least part of the top section and heel section of the external terminal 50 is bonded to the insulating film layer 46 by the adhesive material 49. In a mode illustrated in FIG. 15, only two sections, that is, the top fillet section and the back fillet section that affect the adhesion strength of the external terminal 50 the most, are bonded to the insulating film layer 46 by the adhesive material 49.

Other modes and the methods for manufacturing the printed wiring board 41 and the electronic device 42 are the same as those according to the first and second exemplary embodiments.

According to the present invention, modes (size, shape, position, number, and the like) of the connecting opening section(s) (the first and second opening sections and step section(s)) can be changed depending on the type (shape or size) of an electronic element mounted on the printed wiring board or the type (shape or size) of the external terminal(s) of the electronic element. Namely, the present invention is applicable to mounting various types of electronic elements. In addition, the amount of conductive paste and adhesive material can be adjusted based on required connection reliability, by changing modes of the connecting opening section(s), and thus, manufacturing costs can be reduced.

In the present invention, as the electronic element, various types of electronic elements are applicable, examples of which include an active element such as a semiconductor element and a passive element such as a capacitor.

The printed wiring board, the electronic device, and the method for manufacturing the electronic device according to the present invention have thus been described based on the above exemplary embodiments. However, the present invention is not limited to the above exemplary embodiments. Needless to say, various variations, modifications, and adjustments of the above exemplary embodiments are possible within the scope of the present invention and based on basic technical concepts of the present invention. In addition, various combinations, substitutions, and selections of various disclosed elements are possible within the scope of the claims of the present invention.

Further problems, objects, and applicable modes of the present invention shall be made apparent by the overall disclosure of the present invention including the claims.

### EXPLANATION OF SYMBOLS

1, 21, 41 printed wiring board
2, 22, 42 electronic device
3, 23, 43 electronic element
4, 24, 44 substrate
5, 25, 45 pad
6, 26, 46 insulating film layer
6a first insulating film layer
6b second insulating film layer
6d third insulating film layer
7, 27, 47 connecting opening section
7a, 27a, 47a first opening section (conductive opening section)
7b, 27b, 47b second opening section (adhesive opening section)
7c, 27c, 47c step section
7d third opening section (second adhesive opening section)
8, 28, 48 conductive paste
9, 29, 49 adhesive material
10, 30, 50 external terminal
23a side surface
71 printed wiring board
72 electronic device
73 electronic element
74 substrate
75 pad
76 solder resist film
77 opening
78 conductive paste
80 external terminal

What is claimed is:

1. A printed wiring board comprising:
a substrate;
pads formed on the substrate; and
an insulating film layer covering a surface of the substrate on which the pads are formed,
wherein the insulating film layer comprises at least one connecting opening section each exposing at least part of one of the pads, and
wherein at least part of an inner wall of the connecting opening section comprises at least one step section.

2. The printed wiring board according to claim 1, wherein the step section is formed so that adhesive material can be applied on the step section.

3. The printed wiring board according to claim 1,
wherein the connecting opening section comprises: a first opening section formed for each of the pads so that at least part of each of the pads is exposed; and a second opening section that is formed on the first opening section and that is in communication with the first opening section,
wherein an opening area of the second opening section is larger than an opening area of the first opening section, and
wherein the step section is formed in an area where the first and second opening sections do not overlap.

4. The printed wiring board according to claim 3, wherein the first and second opening sections are formed on a one-to-one basis.

5. The printed wiring board according to claim 4, wherein the first and second opening sections are formed concentrically.

6. The printed wiring board according to claim 3, wherein the connecting opening section comprises a plurality of first opening sections, and the second opening section overlaps with the plurality of first opening sections.

7. The printed wiring board according to claim 1, wherein the connecting opening section has a planar shape extending in one direction, and the step section is formed at least one end of the connecting opening section in a longitudinal direction of the connecting opening section.

8. An electronic device comprising:
a printed wiring board that comprises a substrate, pads formed on the substrate, and an insulating film layer covering a surface of the substrate on which the pads are formed; and
an electronic element that comprises external terminals electrically connected to the pads and that is mounted on the printed wiring board,
wherein the insulating film layer comprises at least connecting opening section each exposing at least part of one of the pads,
wherein at least part of an inner wall of the connecting opening section comprises at least one step section,
wherein the external terminals are electrically connected to the pads by conductive paste applied on the pads, and
wherein the electronic element is bonded to the printed wiring board by adhesive material applied on the step section.

9. The electronic device according to claim 8,
wherein the connecting opening section comprises: a first opening section formed for each of the pads so that at least part of each of the pads is exposed; and a second opening section that is formed on the first opening section and that is in communication with the first opening section,
wherein an opening area of the second opening section is larger than an opening area of the first opening section and the first and second opening sections are formed on a one-to-one basis,
wherein the step section is formed in an area where the first and second opening sections do not overlap, and
wherein the external terminals of the electronic element are bonded to the insulating film layer by the adhesive material.

10. The electronic device according to claim 8,
wherein the connecting opening section comprises a plurality of first opening sections each formed for one of the pads so that at least part of each of the pads is exposed; and a second opening section that is formed on the first opening sections and that is in communication with the first opening sections,
wherein an opening area of the second opening section is larger than an opening area of each of the first opening sections, and the second opening section overlaps with the plurality of first opening sections,
wherein the step section is formed in an area where the first and second opening sections do not overlap, and
wherein at least part of the side surface of the electronic element is bonded to the insulating film layer by the adhesive material.

11. The electronic device according to claim 8,
wherein the connecting opening section comprises a first opening section formed for each of the pads so that at least part of each of the pads is exposed; and a second opening section that is formed on the first opening section and that is in communication with the first opening section,
wherein an opening area of the second opening section is larger than an opening area of the first opening section,
wherein the connecting opening section has a planar shape extending in one direction,
wherein the step section is formed at least one end of the connecting opening section in a longitudinal direction of the connecting opening section in an area where the first and second opening sections do not overlap, and
wherein each of the external terminals has a strip shape, is arranged in a longitudinal direction of the connecting opening section, and is bonded to the insulating film layer by the adhesive material.

12. The electronic device according to claim 8, wherein the connecting opening section is filled with at least the conductive paste and the adhesive material, and the adhesive material is applied extending from the step section to a surface of the insulating film layer.

13. A method for manufacturing an electronic device in which an electronic element is mounted on a printed wiring board, the method comprising:
forming a printed wiring board comprising: an insulating film layer covering a surface of a substrate on which a pad is formed; and at least one connecting opening section exposing at, least part of the pad, at least part of an inner wall of the connecting opening section comprising at least one step section;
applying conductive paste on the pad for electrically connecting an external terminal of the electronic element and the pad;
applying adhesive material on the step section;
mounting the electronic element on the printed wiring board so that the external terminal is positioned in the connecting opening section; and
hardening the conductive paste and the adhesive material to electrically connect the external terminal and the pad by the conductive paste and to bond the printed wiring board and the electronic element by the adhesive material.

14. The method for manufacturing an electronic device according to claim 13, wherein the external terminal and the insulating film layer are bonded by the adhesive material.

15. The method for manufacturing an electronic device according to claim 13, wherein at least part of a side surface of the electronic element and the insulating film layer are bonded by the adhesive material.
